(19) United States
(12) Patent Application Publication
(10) Pub. No.: US 2006/0273333 A1
(43) Pub. Date: Dec. 7, 2006

(54) LIGHT EMITTING DIODE AND METHOD OF FABRICATING THEREOF

(76) Inventors: Liang-Wen Wu, Tao-Yung Hsien (TW); Ming-Sheng Chen, Tao-Yung Hsien (TW); Fen-Ren Chien, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,825

(22) Filed: Aug. 18, 2005

(30) Foreign Application Priority Data
Jun. 3, 2005 (TW) 94118308

(51) Int. Cl. H01L 29/22

(52) U.S. Cl. 257/94

(57) ABSTRACT

A light emitting diode (LED) is made of a substrate and an epitaxial structure. A surface of the epitaxial structure has many mass transferred patterns. The mass transferred patterns are formed by a mass transfer method to deform an original rough surface of the epitaxial structure. The surface topography of the mass transferred patterns is smoother and more gradual than that of the original rough surface of the epitaxial structure, and thus the light extraction efficiency of the LED is improved. In addition, the issue of instrument detection errors related to device positioning due to the roughness or the patterns of the LED surface can be reduced.

### CROSS-REFERENCE TO RELATED APPLICATION

This application claims the priority benefit of Taiwan application serial no. 9411 8308, filed on Jun. 3, 2005. All disclosure of the Taiwan application is incorporated herein by reference.

### BACKGROUND OF THE INVENTION

1. Field of the Invention

The present invention relates to a light emitting diode (LED) and fabrication method thereof. In particular, it relates to a LED having increased light extraction efficiency and the fabrication method thereof.

2. Description of the Related Art

The typical light emitting diode (LED) efficiency can be classified as internal quantum efficiency and external quantum efficiency. The internal quantum efficiency describes the ratio of externally inputted carriers that are converted into photons. It is mainly related to the epitaxy of the material of the device and to the device structure; external quantum efficiency is the product of internal quantum efficiency and light extraction efficiency, wherein the light extraction efficiency is related to the proportion of photons generated inside the device which is dissipated externally of the device. The typical light emitting diode efficiency describes the external quantum efficiency, which is derived from the detected photon count external to the device and is compared with the input carrier.

Because Group III nitrides have a continuous and wider bandgap, they are therefore widely used as the light emitting diode. Because gallium nitride can be combined with indium nitride (InN) and aluminum nitride (AIN) to form ternary or quaternary compounds; therefore, the light emitting diode wavelength is allowed to encompass the infrared and ultraviolet light ranges by changing the ratio of the Group III elements. LED is used extensively in small and large outdoor displays, vehicle instrumentation panel, automobile lamp, cellular phone, warning light, indicator lamp, advertisement billboard, and traffic light. It thus improves and enriches quality of life for mankind.

The early development for light emitting diode using gallium nitride is in the improvement for the structure and quality of the epitaxy for improving internal quantum efficiency. However, the research for light extraction efficiency enhancement currently has received much attention, thus allowing for further improvement for the light emitting diode efficiency. In the area of improving the light extraction efficiency, the index of refraction for the light emitting diode of conventional gallium nitride series with respect to air is 2.5 to 1 respectively. Because the index of refraction for the gallium nitride series light emitting diode is higher, the internal total reflection can easily be formed. The formed photons are not easily released outside of the gallium nitride series light emitting diode because of internal total reflection.

### SUMMARY OF THE INVENTION

The objective for the present invention is for providing a light emitting diode, which has increased light extraction efficiency.

Another objective for the present invention is for providing a fabrication method for a light emitting diode to obtain higher light extraction efficiency and to minimize the issues of instrument detection errors related to device positioning caused by the surface roughness or patterns (which is the n,p pad color difference) of the light emitting diode.

The present invention proposes a light emitting diode, which includes a substrate and an epitaxial structure disposed above the substrate. The surface for the epitaxial structure has a plurality of mass transferred patterns. The mass transferred patterns are made by a mass transfer method, which makes the original rough surface of the epitaxial structure to undergo deformation, wherein a surface topography of the mass transferred pattern is smoother and more gradual than that of the original surface of the epitaxial structure.

According to the light emitting diode for an embodiment of the present invention, the distance between each of the aforementioned mass transferred pattern is 0.1 μm to 5 μm. Furthermore, the surface of each of the mass transferred pattern is similar to the surface for a microlens.

According to the light emitting diode for an embodiment of the present invention, the aforementioned substrate includes a surface patterned substrate.

According to the light emitting diode for an embodiment of the present invention, a regrowth mask which is disposed within the epitaxial structure is further included.

According to the light emitting diode for an embodiment of the present invention, the aforementioned epitaxial structure includes a buffer layer disposed on the substrate, a first contact layer disposed on the buffer layer, an active layer disposed on the first contact layer, a clad layer disposed on the active layer, and a second contact layer disposed on the clad layer. In addition, the light emitting diode described in an embodiment of the present invention further includes a first electrode disposed on the first contact layer, a surface disposed on the second contact layer, and a second electrode on the mass transferred pattern and a transparent conductive layer, wherein the transparent conductive layer and the second electrode do not mutually overlap. Furthermore, the aforementioned transparent conductive layer includes a metal layer or a transparent conductive oxide layer.

According to the light emitting diode for an embodiment of the present invention, the aforementioned first contact layer includes a n-type contact layer, the second contact layer includes a p-type contact layer, and the clad layer includes a p-type clad layer. Furthermore, the light emitting diode further includes a regrowth mask, which is disposed between the substrate and the active layer.

The present invention further proposes a fabrication method for a light emitting diode, which an epitaxial structure on a substrate is formed, wherein the surface for the epitaxial structure has a plurality of first patterns. Later, using a mass transfer method, a plurality of second patterns are formed as the first pattern for the above surface undergoes deformation, wherein a surface topography of the second pattern is smoother and more gradual than that of each of the first pattern.

According to the fabrication method for the light emitting diode described in an embodiment of the present invention during the aforementioned mass transfer, the mass transfer phenomenon occurs at a temperature between 800° C. and 1400° C.

According to the fabrication method for the light emitting diode described in an embodiment of the present invention, the distance between each of the aforementioned second patterns is 0.1 μm to 5 μm. In addition, the height of each of the first pattern is between 500 angstrom and 10000 angstrom, and the width is between 0.1 μm and 5μm.

According to the fabrication method for the light emitting diode described in an embodiment of the present invention, a buffer layer, a first contact layer, an active layer, a clad layer, and a second contact layer are sequentially formed above the substrate in the aforementioned procedure for providing an epitaxial structure on the substrate. In addition, the aforementioned first patterns are formed using a fabrication method on the surface of the second contact layer.

According to the fabrication method for the light emitting diode described in an embodiment of the present invention, a surface patterned substrate as the substrate is provided in the aforementioned procedure for providing the epitaxial structure on the substrate, wherein the surface for the surface patterned substrate has surface patterns. Later, a buffer layer, a first contact layer, an active layer, a clad layer, and a second contact layer are sequentially formed above the substrate.

According to the fabrication method for the light emitting diode described in an embodiment of the present invention, the buffer layer, the first contact layer, the active layer, and the clad layer are sequentially formed above the substrate in the aforementioned procedure for providing the epitaxial structure on the substrate. Thereafter, the second contact layer is formed on the clad layer. Using the changes for the epitaxial conditions, the aforementioned first pattern is formed on the second contact layer.

According to the fabrication method for the light emitting diode described in an embodiment of the present invention, a regrowth mask in the epitaxial structure is formed in the aforementioned procedure for providing the epitaxial structure on the substrate, wherein the position for the regrowth mask pattern and the first pattern are mirror images of one another. In addition, the regrowth mask can be formed between the substrate and the active layer further using an epitaxial method such as epitaxial lateral over growth (ELOG) or PENDEO for forming the light emitting diode crystal .

According to the fabrication method for the light emitting diode described in an embodiment of the present invention, after the aforementioned procedure, the first electrode is then formed on the first contact layer, and the second electrode and the transparent conductive layer are formed above the second contact layer surface and second pattern, wherein the transparent conductive layer and the second electrode do not mutually overlap.

The present invention makes the originally rough or patterned surface for the epitaxial structure of the light emitting diode to undergo deformation by adopting the mass transfer method; as a result, the light extraction efficiency for the light emitting diode can be increased, and at the same time, the issues of instrument detection errors related to device positioning caused by the light emitting diode surface roughness or patterns are minimized.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are cross-sectional views schematically illustrating the fabrication process of the light emitting diode, according to a first embodiment of the present invention.

FIG. 2A to FIG. 2C are cross-sectional views schematically illustrating the fabrication process of the light emitting diode, according to a second embodiment of the present invention.

FIG. 3A to FIG. 3C are cross-sectional views schematically illustrating the fabrication process of the light emitting diode, according to a third embodiment of the present invention.

FIG. 4A to FIG. 4C are cross-sectional views schematically illustrating the fabrication process of the light emitting diode, according to a fourth embodiment of the present invention.

FIG. 5 is an enlarged cross-sectional view schematically illustrating the mass transferred pattern, according to an embodiment of the present invention.

### DESCRIPTION OF THE PREFERRED EMBODIMENTS

A principle for the present invention is based on using a mass transfer method to make the already roughened or patterned surface of the light emitting diode to undergo deformations for achieving the objective of the present invention. The following are several embodiments as examples, but the application for the present invention is not limited thereto.

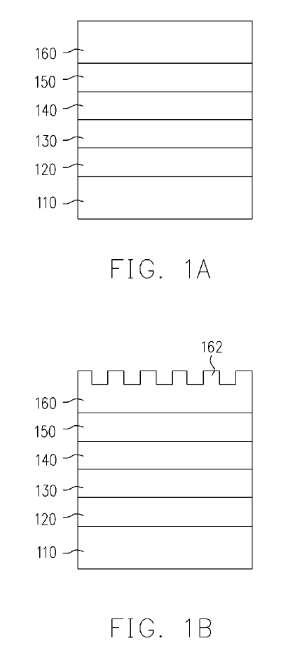

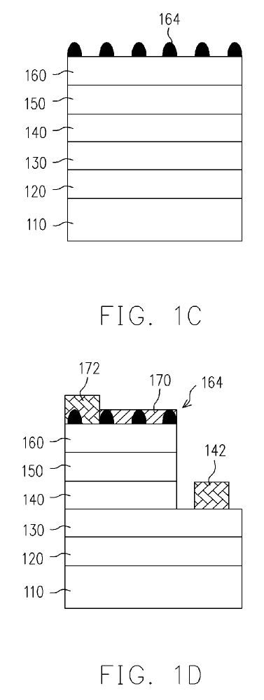

FIG. 1A to FIG. 1D are cross-sectional diagrams schematically illustrating the fabrication process of the light emitting diode, according to the first embodiment of the present invention, wherein the FIG. 1D is a finished structure diagram for the light emitting diode.

Referring to FIG. 1A, an epitaxial structure 120-160 is first provided on a substrate 110. In this embodiment, the material of the substrate 110 is a C-Plane sapphire, R-Plane sapphire, A-Plane sapphire, SiC (for example, 6H—SiC or 4H—SiC), other materials that are suitable to be used as the substrate 110 including Si, ZnO, GaAs or MgAl₂O₄, or single crystalline compounds with lattice constant substantially the same as the semiconductor nitride. And the method for forming the epitaxial structure is the sequential forming of a buffer layer 120, a first contact layer 130, an active layer 140, a clad layer 150, and a second contact layer 160 on a substrate 110, wherein the buffer layer 120 may be fabricated, for example, from any of the Group III-V compounds that can be generally defined as: AlₐGa_{b}In_{1-a-b}N, wherein 0≦a, b<1, a+b≦1.

The first contact layer 130 is, for example, made of gallium nitride (GaN) series material for forming the n-type contact layer. The active layer 140 is made of indium gallium nitride. The clad layer 150 is, for example, constructed of a material from the gallium nitride Group III to IV series for forming a p-type clad layer. And the second contact layer 160 is, for example, constructed from the gallium nitride series material for forming a p-type contact layer.

Thereafter, referring to FIG. 1B, a plurality of first patterns 162 are formed using a fabrication method at the second contact layer 160 surface.

Later, referring to FIG. 1C, using a mass transfer method, the first pattern 162 undergoes deformation to form a plurality of second patterns 164, wherein a surface topography of each of the second pattern 164 is smoother and more gradual than that of each of the first pattern 162. And the second pattern 164, because of being fabricated by the mass transfer method, can therefore also be referred to as a mass transferred pattern. In this embodiment, the mass transfer phenomenon occurs at a temperature between 800° C. and 1400° C., wherein the preferred temperature is between 1000° C. and 1200° C.

Later, referring to FIG. 1D, an electrode 142 is formed on the first contact layer 130. It is a negative electrode, and can be constructed of Al, Pt, Pd, Co, Mo, Be, Au, Ti, Cr, Sn, Ta, TiN, TiWNₓ (x≧0), WSi_{y} (y≧0), or other similar metal or alloy in the form of single layer or multiple layers. At above the surface of the second contact layer 160 and the second pattern 164, another electrode 172 and a transparent conductive layer 170 which are not mutually overlapping are formed. The electrode 172 is a positive electrode, and can be constructed from Ni, Pt, Pd, Co, Be, Au, Ti, Cr, Sn, Ta, TiN, TiWNₓ (x≧0), WSi_{y} (y≧0), or other similar metal or alloy in the form of single layer or multiple layers. Furthermore, the transparent conductive layer 170 can be a metal layer or a transparent conductive oxide layer, wherein the metal layer is constructed of Ni, Pt, Pd, Co, Be, Au, Ti, Cr, Sn, Ta, or other similar metal or alloy in the form of single layer or multiple layers. In addition, the transparent conductive oxide layer is made of ITO, CTO, ZnO:Al, ZnGa₂O₄, SnO₂:Sb, Ga₂O₃:Sn, AglnO₂:Sn, In₂O₃:Zn, CuAlO₂, LaCuOS, NiO, CuGaO₂, or SrCu₂O₂ fabricated in the form of single layer or multiple layers.

The enlarged cross-sectional view shown in FIG. 5 illustrates the mass transferred pattern formed after the aforementioned procedure in the aforementioned FIG. 1C. The surface topography of the mass transferred pattern 510 (which is also the second pattern 164 as shown in FIG. 1C) formed on the surface of the epitaxial structure 500 is smoother and more gradual than that of the original surface 520 (which is also the surface of the first pattern 162 as shown in FIG. 1B) of the epitaxial structure 500. In addition, the surface of the mass transferred pattern 510 is similar to the surface for a microlens, which helps to extract light out of the light emitting diode. In addition, a smoother surface minimizes the device n, p pad color difference issue caused by the typical light emitting diode surface roughness. Furthermore, in this embodiment, the width 502 for the first pattern 520 is, for example, between 0.1 μm and 5 μm, and the preferred width is between 0.1 μm and 2 μm. And the height of the first pattern 520, for example, is between 500 angstrom and 10000 angstrom, and the preferred height is between 1000 angstrom and 5000 angstrom. Furthermore, the distance 506 between each mass transferred pattern 510 is about between 0.1 μm and 5 μm, and the preferred distance is between 0.1 μm and 2 μm.

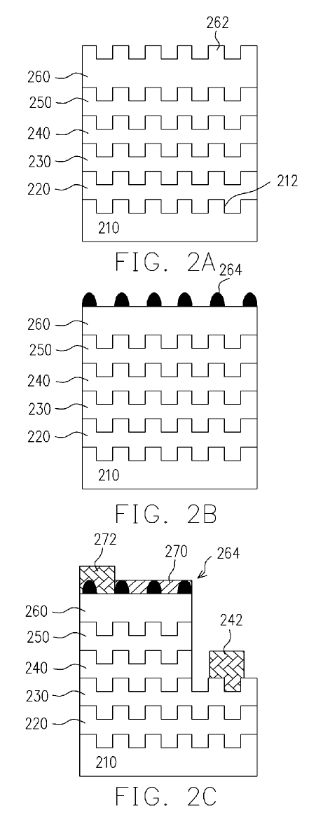

FIG. 2A to FIG. 2C are cross-sectional diagrams schematically illustrating the fabrication process of the light emitting diode, according to the second embodiment of the present invention, wherein FIG. 2C is a finished structure diagram for the light emitting diode.

Referring to FIG. 2A, a surface patterned substrate 210 is first provided for use as the substrate in this embodiment, wherein a surface pattern 212, a buffer layer 220, a first contact layer 230, an active layer 240, a clad layer 250, and a second contact layer 260 are sequentially formed above the surface for the surface patterned substrate 210. Because each of the aforementioned layers (including the buffer layer 220, the first contact layer 230, the active layer 240, the clad layer 250, and the second contact layer 260) is influenced by the surface pattern 212 of the surface patterned substrate 210, a plurality of first patterns 262 are therefore formed on the second contact layer 260. And the materials for the aforementioned substrate 210 and epitaxial structure 220-260 are referenced from the descriptions for the first embodiment.

Later, referring to FIG. 2B, the mass transfer method is used for undergoing deformation at the first pattern 262 for forming a plurality of second patterns 264, wherein a surface topography of the second pattern 264 is smoother and more gradual than that of the first pattern 262. And the second pattern 264 is referred to as a mass transferred pattern. In this embodiment, the mass transfer phenomenon occurs at a temperature between 800° C. and 1400° C., wherein the preferred temperature is between 1000° C. and 1200° C.

Later, referring to FIG. 2C, an electrode 242 is formed on the first contact layer 230. Another electrode 272 and a transparent conductive layer 270 which do not mutually overlap are formed above the second contact layer 260 and the surface of the second pattern 264. In the present embodiment, the electrode 242 is a negative electrode, and the electrode 272 is a positive electrode. In addition, the material of the aforementioned electrodes 242, 272 and the transparent conductive layer 270 are described in reference to the first embodiment.

In addition, the enlarged cross-sectional view shown in FIG. 5 illustrates the mass transferred pattern formed after the aforementioned procedure in the aforementioned FIG. 2B.

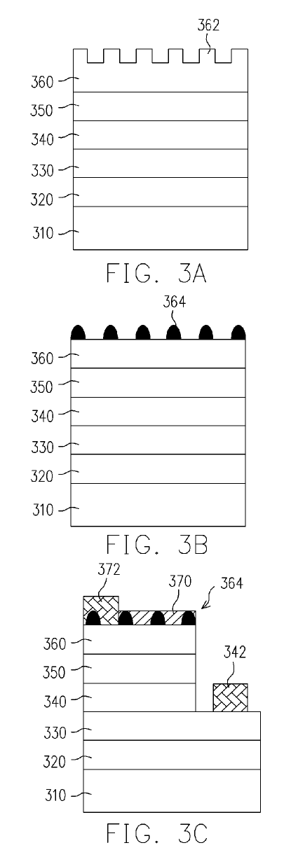

FIG. 3A to FIG. 3C are cross-sectional diagrams schematically illustrating the fabrication process of the light emitting diode, according to the third embodiment of the present invention, wherein FIG. 3C is a finished structure diagram for the light emitting diode.

Referring to FIG. 3A, a buffer layer 320, a first contact layer 330, an active layer 340, and a clad layer 350 are formed above a substrate 310 in this embodiment. Thereafter, a second contact layer 360 is formed on the clad layer 350, and using the changes of the epitaxial conditions, a plurality of first patterns 362 are allowed to be formed on the second contact layer 360.

Later, referring to FIG. 3B, using the mass transfer method, the first pattern 362 undergoes deformation and a plurality of second patterns 364 are formed, wherein a surface topography of the second pattern 364 is smoother and more gradual than that of the first pattern 362. And the second pattern 364 is a mass transferred pattern. In this embodiment, the mass transfer phenomenon occurs at a temperature between 800° C. and 1400° C., wherein the preferred temperature is between 100° C. and 1200° C.

Later, referring to FIG. 3C which is the same as the first embodiment in FIG. 1D, an electrode 342 is formed on the first contact layer 330. Another electrode 372 and a transparent conductive layer 370 which do not mutually overlap are formed above the second contact layer 360 and the surface of the second pattern 364.

The enlarged cross-sectional view shown in FIG. 5 illustrates the result after the aforementioned procedure in FIG. 3B in which the mass transferred pattern is formed. No further discussions are needed.

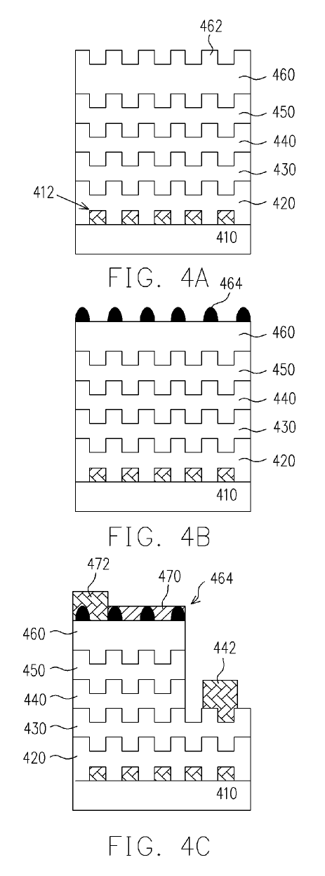

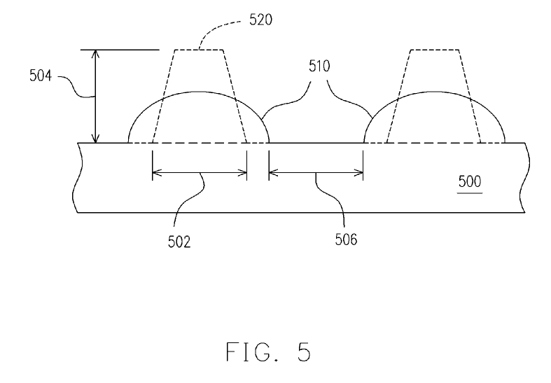

FIG. 4A to FIG. 4C are cross-sectional schematic diagrams illustrating the fabrication process of the light emitting diode, according to the fourth embodiment of the present invention, wherein FIG. 4C is a finished structure diagram for the light emitting diode.

Referring to FIG. 4A, the forming of a regrowth mask 412 on the substrate 410 is described in this embodiment. And the pattern for a regrowth mask 412 and the position for a first pattern 462 are mirror images of one another. Wherein, the material of the regrowth mask 412 is, for example, SiO2 or SiNx. Although the regrowth mask 412 in the above drawing is disposed above the substrate 410, nevertheless, the location of the regrowth mask 412 is not limited thereto. For example, a buffer layer 420, a first contact layer 430, an active layer 440, a clad layer 450, and a second contact layer 460 are sequentially formed above a substrate 410 in the fabrication process. The regrowth mask 412 is also selected to be fabricated in the buffer layer 420, in the first contact layer 430, or between the substrate 410 and the active layer 440. Using the epitaxial method of epitaxial lateral over growth (ELOG) or PENDEO, the crystal is formed for the light emitting diode.

Thereafter, referring to FIG. 4B, the mass transfer method is used for making the first pattern 462 to undergo deformations for forming a plurality of second patterns 464, wherein a surface topography of the second pattern 464 is smoother and more gradual than that of the first pattern 462, and the second pattern 464 is a mass transferred pattern. In this embodiment, the mass transfer phenomenon occurs at a temperature between 800° C. and 1400° C., wherein the preferred temperature is between 1000° C. and 1200° C.

Referring to FIG. 4C, which is the same as FIG. 2C in the second embodiment, an electrode 442 is formed on the first contact layer 430. Another electrode 472 and a transparent conductive layer 470 which do not mutually overlap are formed above the second contact layer 460 and the surface of the second pattern 464.

The enlarged cross-sectional view as shown in FIG. 5 illustrates the mass transferred pattern formed after the aforementioned procedure in the fourth embodiment.

In summary, a key element for the present invention is for applying the mass transfer method to the fabrication process for the light emitting diode to cause the surface of the epitaxial structure which is originally roughened or patterned to undergo deformation, thus increasing the light extraction efficiency for the light emitting diode, at the same time the issues of the instrument detection errors relating to device positioning caused by the light emitting diode surface roughness or pattern are reduced.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A light emitting diode, comprising a substrate and an epitaxial structure disposed on the substrate, wherein comprising:
a surface of the epitaxial structure having a plurality of mass transferred patterns, forming the mass transferred patterns by means of a mass transfer method undergoing deformations of the original rough surface of the epitaxial structure, wherein a surface topography of the mass transferred pattern is smoother and more gradual than a surface topography of the original surface of the epitaxial structure.

2. The light emitting diode according to claim 1, wherein the distance between each of the mass transferred patterns is between 0.1 μm and 5 μm.

3. The light emitting diode according to claim 1, wherein the surface of each of the mass transferred pattern is the same as the surface of a microlens.

4. The light emitting diode according to claim 1, wherein the substrate comprises C-Plane sapphire, R-Plane sapphire, A-Plane sapphire, SiC, Si, ZnO, GaAs, spinel, or single crystalline compounds with lattice constant same as semiconductor nitrides.

5. The light emitting diode according to claim 1, wherein the substrate comprises a surface patterned substrate.

6. The light emitting diode according to claim 1, further comprising a regrowth mask disposed in the epitaxial structure.

7. The light emitting diode according to claim 1, wherein the epitaxial structure comprising:
a buffer layer, disposed on the substrate;
a first contact layer, disposed on the buffer layer;
an active layer, disposed on the first contact layer;
a clad layer, disposed on the active layer; and
a second contact layer, disposed on the clad layer.

8. The light emitting diode according to claim 7, wherein:
material of the buffer layer comprising AlₐGa_{b}In_{1-a-b}N, wherein 0≦a,b<1, a+b≦1;
material of the first contact layer comprising gallium nitride series material;
material of the active layer comprising indium gallium nitride;
material of the clad layer comprising gallium nitride series material; and material of the second contact layer comprising gallium nitride series material.

9. The light emitting diode according to claim 7, further comprising a first electrode, disposed on the first contact layer;
a second electrode, disposed on the second contact layer and the surfaces of the mass transferred patterns; and
a transparent conductive layer, disposed on the second contact layer and a plurality of the mass transferred patterns, wherein the transparent conductive layer and the second electrode do not mutually overlap.

10. The light emitting diode according to claim 9, wherein the first electrode is a negative electrode, wherein the first electrode is made of Al, Pt, Pd, Co, Mo, Be, Au, Ti, Cr, Sn, Ta, TiN, TiWNx or WSiy fabricated in the form of metal or alloy in single layer or multiple layers.

11. The light emitting diode according to claim 9, wherein the second electrode is a positive electrode, wherein the second electrode is made of Ni, Pt, Pd, Co, Be, Au, Ti, Cr, Sn, Ta, TiN, TiWNx , or WSiy fabricated in the form of metal or alloy in single layer or multiple layers.

12. The light emitting diode according to claim 9, wherein the transparent conductive layer comprising a metal layer or a transparent conductive oxide layer.

13. The light emitting diode according to claim 12, wherein the metal layer is made of Ni, Pt, Pd, Co, Be, Au, Ti, Cr, Sn or Ta fabricated in the form of metal or alloy in single layer or multiple layers.

14. The light emitting diode according to claim 12, wherein the transparent conductive oxide (TCO) layer is made from at least one material of ITO, CTO, ZnO:Al, ZnGa₂O₄, SnO₂:Sb, Ga₂O₃:Sn, AglnO₂:Sn, In₂O₃:Zn, CuAlO₂, LaCuOS, NiO, CuGaO₂, or SrCu₂O₂ fabricated in the form of single layer or multiple layers.

15. The light emitting diode according to claim 7, wherein the first contact layer comprising a n-type contact layer and the second contact layer comprising a p-type contact layer.

16. The light emitting diode according to claim 7, wherein the clad layer comprises a p-type clad layer.

17. The light emitting diode according to claim 7, further comprises a regrowth mask disposed between the substrate and the active layer.

18. A fabrication method for a light emitting diode, comprising providing an epitaxial structure on a substrate, wherein a surface of the epitaxial structure has a plurality of first patterns; and
undergoing deformation to the first pattern of the surface and forming a plurality of second patterns using a mass transfer method, wherein a surface topography of each of the second pattern is smoother and more gradual than a surface topography of each of the first pattern.

19. The fabrication method for the light emitting diode according to claim 18, wherein the mass transfer phenomenon occurs at temperature between 800° C. and 1400° C. in the mass transfer method.

20. The fabrication method for the light emitting diode according to claim 18, wherein the distance between each of the second patterns is between 0.1 μm and 5 μm.

21. The fabrication method for the light emitting diode according to claim 18, wherein the height of each of the first pattern is between 500 angstrom and 10000 angstrom.

22. The fabrication method for the light emitting diode according to claim 18, wherein the width of each of the first pattern is between 0.1 μm and 5 μm.

23. The fabrication method for the light emitting diode according to claim 18, wherein the procedure for providing the epitaxial structure on the substrate comprising:
forming a buffer layer, a first contact layer, an active layer, a clad layer, and a second contact layer sequentially above the substrate; and
forming the plurality of first patterns using fabrication method at the surface of the second contact layer.

24. The fabrication method for the light emitting diode according to claim 23, further comprising:
forming a first electrode on the first contact layer; and
forming a second electrode and a transparent conductive layer on the second contact layer and a plurality of second patterns, wherein the transparent conductive layer and the second electrode do not mutually overlap.

25. The fabrication method for the light emitting diode according to claim 18, wherein the procedure for providing the epitaxial structure on the substrate comprising:
providing a surface patterned substrate as the substrate, wherein the surface of the surface patterned substrate having a plurality of surface patterns; and
forming a buffer layer, a first contact layer, an active layer, a clad layer, and a second contact layer sequentially above the substrate.

26. The fabrication method for the light emitting diode according to claim 25, further comprising:
forming a first electrode on the first contact layer; and
forming a second electrode and a transparent conductive layer on the second contact layer and a plurality of second patterns, wherein the transparent conductive layer and the second electrode do not mutually overlap.

27. The fabrication method for the light emitting diode according to claim 18, wherein the procedure for providing the epitaxial structure on the substrate comprising:
forming a buffer layer, a first contact layer, an active layer, and a clad layer sequentially above the substrate; and
forming a second contact layer on the clad layer , and forming a plurality of first patterns on the second contact layer using changes in epitaxial conditions.

28. The fabrication method for the light emitting diode according to claim 27, further comprising:
forming a first electrode on the first contact layer; and
forming a second electrode and a transparent conductive layer on the second contact layer and a plurality of second patterns, wherein the transparent conductive layer and the second electrode do not mutually overlap.

29. The fabrication method for the light emitting diode according to claim 18, wherein the procedure for providing the epitaxial structure on the substrate comprising:
forming a regrowth mask in the epitaxial structure, wherein the pattern of the regrowth mask and the position of a plurality of first patterns are mirror images of one another.

30. The fabrication method for the light emitting diode according to claim 29, wherein the procedure for providing the epitaxial structure on the substrate comprising:
forming a buffer layer, a first contact layer, an active layer, a clad layer, and a second contact layer sequentially above the substrate, wherein the regrowth mask is formed on the substrate, in the buffer layer, or in the first contact layer.

31. The fabrication method for the light emitting diode according to claim 30, further comprising:
forming a first electrode on the first contact layer; and
forming a second electrode and a transparent conductive layer on the second contact layer and a plurality of second patterns, wherein the transparent conductive layer and the second electrode do not mutually overlap.

32. The fabrication method for the light emitting diode according to claim 29, wherein the procedure for providing the epitaxial structure on the substrate comprising:
forming a buffer layer, a first contact layer, an active layer, a clad layer, and a second contact layer sequentially above the substrate, wherein:
forming the regrowth mask between the substrate and the active layer; and
forming the cystal of the light emitting diode using epitaxial method of epitaxial lateral over growth (ELOG) or PENDEO.

33. The fabrication method for the light emitting diode according to claim 32, further comprising:
forming a first electrode on the first contact layer; and
forming a second electrode and a transparent conductive layer on the second contact layer and a plurality of second pattern, wherein the transparent conductive layer and the second electrode do not mutually overlap.
